(19) United States
(12) Patent Application Publication
(10) Pub. No.: US 2008/0182398 A1
(43) Pub. Date: Jul. 31, 2008

(54) Varied Solder Mask Opening Diameters Within a Ball Grid Array Substrate

(76) Inventors: Burton J. Carpenter, Austin, TX (US); Patrice L. Langford, Round Rock, TX (US); Wayne S. Lindsay, Austin, TX (US); Boon Yew Low, Selangor (MY)

Correspondence Address: HAMILTON & TERRILE, LLP, P.O. BOX 203518, AUSTIN, TX, 78720, US

(21) Appl. No.: 11/668,689

(22) Filed: Jan. 30, 2007

(51) Int. Cl. H01L 21/44

(52) U.S. Cl. 438/612

(57) ABSTRACT

A packaging assembly, such as a ball grid array package, is formed to reduce the effects of warpage by varying the size of solder ball aperture openings in the solder mask layer so that smaller solder ball aperture openings are located on the carrier substrate areas where warpage is higher and larger solder ball aperture openings are located on the carrier substrate where warpage is lower.

### BACKGROUND OF THE INVENTION

1. Field of the Invention

The present invention is directed in general to the field of semiconductor devices. In one aspect, the present invention relates to electronic component packaging.

2. Description of the Related Art

One of the stages in the manufacturing process of an integrated circuit (IC) is to form a package around a semiconductor chip. The package protects the chip from structural or mechanical damage, and also allows for electrically connecting the chip to other electronic components on a printed circuit board. As electronics technology develops, an increasing number of electrical connections must be squeezed into an increasingly smaller package size in order to meet market expectations. Numerous package types have been or are currently being used in the electronics industry, including the ball grid array (BGA), the land grid array (LGA), and the pin grid array (PGA). Conventional packaging technologies use electrically conductive paths—such as wires, contact pads or layers, conductive vias, conductive traces and/or solder balls—to electrically connect an integrated circuit die to the outside world.

Certain types of device packaging, such as ball grid array packages, can be warped due to differing stress performance of the materials used to form the device. The resulting warpage can prevent ball grid array spheres from forming a solder joint with printed circuit board, especially when the packaging features organic substrates. Prior attempts to address this problem have proved unsuccessful and unduly complex. For example, with the existing industry practice of designing all pads on a substrate with the same solder mask opening diameter, conventional approaches have included using differently-sized solder balls, but these solutions are unwieldy to implement. Accordingly, there exists a need for an array packaging process that reduces warpage, provides improved solder interconnect reliability and overcomes the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description of a preferred embodiment is considered in conjunction with the following drawings, in which:

FIG. 1 illustrates a warped ball grid array package that is applied to a printed circuit board;

FIG. 2 illustrates in cross-sectional form a packaging assembly that includes a solder mask and a carrier substrate in accordance with selected embodiments of the present invention;

FIG. 3 illustrates in cross-sectional form a packaging assembly after attachment to a circuit die, attachment of wirebonding and formation of an encapsulation layer;

FIG. 4 illustrates a perspective view of the packaging assembly depicted in FIG. 3; and

FIG. 5 illustrates in cross-sectional form a packaging assembly after solder balls are formed in differently-sized solder aperture openings to control the relative protrusions of solder balls from the packaged array.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for encapsulating a semiconductor die in a package in which a carrier substrate is secured to an integrated circuit die and to a solder mask layer in which the size of the solder ball openings or apertures is selected to reduce the effects of package warpage. By varying the diameter of the solder ball aperture openings formed in the solder mask layer, different ball heights are effectively produced by virtue of the solder balls being more deeply recessed in the wider solder ball aperture openings, and less deeply recessed in the smaller solder ball aperture openings. In effect, a pad with a larger diameter opening gives more area for the ball to collapse on, thereby reducing the ball height for that pad as compared to a pad having a smaller diameter opening. As will be appreciated, the sizing of the solder ball aperture openings across a package surface may be selectively varied so that, for example, smaller sized openings are used on the periphery of the package while larger sized openings are used in the central area of the package.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a packaged semiconductor device which are not drawn to scale and which do not include every device feature or geometry in order to avoid limiting or obscuring the present invention. It is also noted that, throughout this detailed description, certain materials (such as the solder mask layers) will be formed and selectively removed to fabricate the packaged semiconductor device. Where the specific procedures for forming or removing such materials are not detailed below, conventional techniques to one skilled in the art for depositing, masking, etching, removing or otherwise forming such layers at appropriate thicknesses and dimensions may be used. Such details are well known and not considered necessary to teach one skilled in the art of how to make or use the present invention.

Turning now to FIG. 1, there is illustrated a conventional ball grid array package 8 that is applied to a printed circuit board 6, where warpage in the ball grid array package 8 prevents the formation of a solder joint with the printed circuit board 6. The depicted ball grid array package 8 includes an integrated circuit die 10 attached through conductive traces (not shown) formed in a carrier substrate 12 to a plurality of solder balls 2. To affix the solder balls 2, the ball grid array package 8 includes a solder mask layer 4 that is affixed to the carrier substrate 12 and that has a plurality of uniformly-sized solder ball openings 1. By forming the solder balls 2 in the uniformly-sized solder ball openings 1, each solder ball 2 is affixed in electrical contact with an associated conductive trace. As depicted, the peripheral edges of the carrier substrate 12 are warped or “lifted” up, which can be caused by deformity stress between any constituent layers used to form the ball grid array package 8. Because the solder ball openings 1 are uniformly sized, the uniformly-sized solder balls 2 have the same relative height position with respect to the carrier substrate 12 so that they are no longer aligned in parallel with the surface of the printed circuit board 6, as indicated with the dashed alignment line 14. This prevents the formation of a solder joint with the printed circuit board 6.

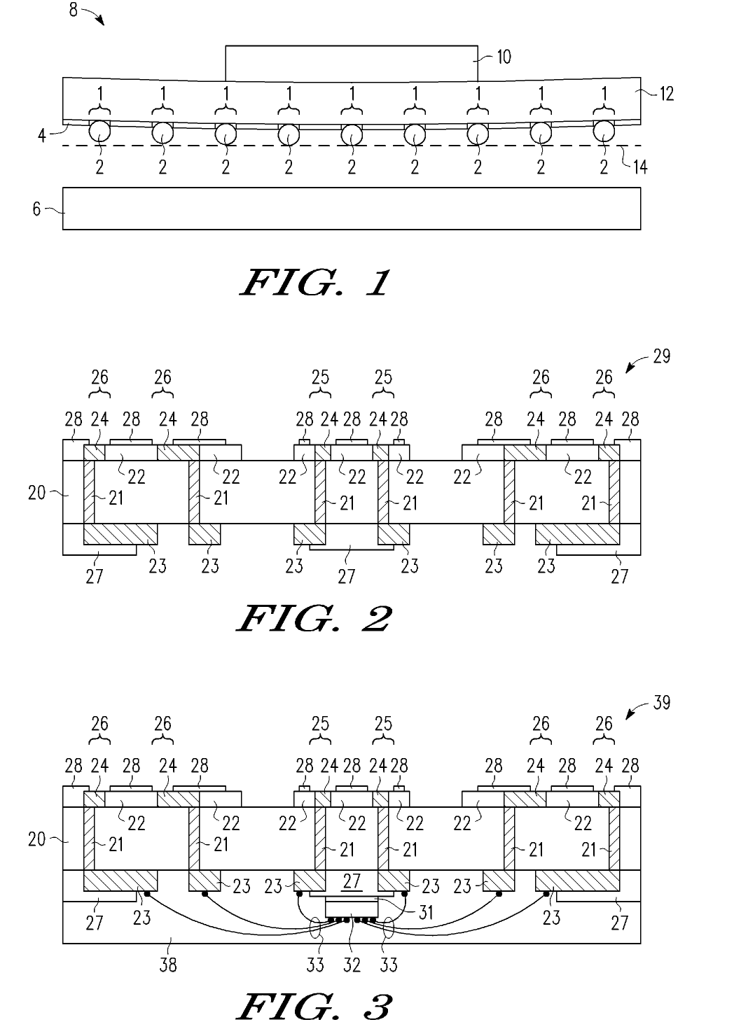

As explained herein, the relative positioning or height of the solder ball elements may be controlled by varying the size of the solder ball openings formed in the package. This may be illustrated with reference to FIG. 2, which illustrates in cross-sectional form a packaging assembly 29 in accordance with selected embodiments of the present invention. The packaging assembly 29 includes a carrier substrate 20 in which are formed one or more via opening that extend between upper and lower surfaces of the carrier substrate 20. As will be appreciated, the carrier substrate 20 may be formed to any desired shape and thickness, and may include any desired features for use in forming a functional semiconductor package. In addition, the carrier substrate 20 may be fabricated with a relatively thin, flexible film of an electrically insulative material (such as an organic polymer resin), or with a rigid, substantially planar member fabricated from any known, suitable materials, including, but not limited to, insulator-coated silicon, a glass, a ceramic, an epoxy resin, bismaleimide-triazine (BT) resin, or any other material known in the art to be suitable for use as a carrier substrate.

The depicted packaging assembly 29 includes a conductive pattern of conductive traces, vias and contact pad areas formed on and through the carrier substrate 20 for purposes of electrically connecting the (subsequently formed) solder balls to the (subsequently attached) integrated circuit die. For example, one or more first contact pads or layers 23 are formed on a lower surface of the carrier substrate 20 and are electrically connected by conductive trace layer(s) to one or more conductive vias 21 formed in the carrier substrate. In addition, one or more second contact pads or layers 24 are formed and positioned peripherally to underlie the (subsequently formed) solder balls and are electrically connected by conductive trace layer(s) to one or more conductive vias 21 formed in the carrier substrate. As will be appreciated, one or more internal conductive layers (not shown) may be formed in the carrier substrate 20, though for purposes of simplifying the description, they are represented by the conductive vias 21. Finally, individual circuit lines formed on a surface of the carrier substrate (e.g., from second layers 24) are electrically separated from one another with selectively formed dielectric layers (e.g., insulator layers 22). In selected embodiments, the second contact layer(s) 24 may be arranged in one or more area arrays, although other arrangements may also be used. As will be appreciated, the conductive traces and contact areas may be formed from any conductive material, including but not limited to conductively doped polysilicon, a conductive metal or metal alloy, conductive or conductor-filled elastomer, or any other conductive material used for electrical connections known to those skilled in the art.

The depicted packaging assembly 29 also includes a solder mask layer 28 which may be selectively formed over the upper surface of the carrier substrate 20 (and any conductive layer(s) and dielectric layer(s)) as a substantially planar member. In addition, a solder mask layer 27 may be selectively formed over the lower surface of the carrier substrate 20 for use in defining solder ball contact areas for flip-chip applications where the integrated circuit is electrically connected by solder material (instead of wire bonds) to the conductive traces, vias and contact pad areas formed on and through the carrier substrate 20. In various embodiments, the solder mask layers 27, 28 may be selectively etched or screen printed to form a plurality of openings, such as openings 25, 26 formed in the solder mask layer 28. As depicted, the solder mask layer 28 is formed or patterned with openings in which solder balls will subsequently be placed, and may also include additional openings (such as the opening between the 25 solder ball apertures and the 26 solder ball apertures, as shown in FIG. 2). However, it will be appreciated that the additional openings are not required, in which case the solder mask layer openings are formed only where solder balls will subsequently be placed. While the openings may be formed to overlie the conductive vias 21 formed in the carrier substrate 20, selected embodiments of the present invention also include a plurality of solder ball apertures 25, 26 formed in the solder mask layer 28 that are positioned so as to expose corresponding second contact areas 24 of the carrier substrate 20 and to facilitate the formation of solder balls or other discrete conductive elements 50, 52, 54 (depicted in FIG. 5) on the second contact layers 24. In the example depicted in FIG. 2, the solder mask layer 28 is formed over a substantial portion of at least the upper surface of the carrier substrate 20, and is secured to the carrier substrate 20 and to the second layer 24 using any desired technique, such as using an adhesive material to attach the solder mask layer 28. Alternatively, the solder mask layer 28 may be prefabricated and adhered directly to the carrier substrate 20 using processes known in the art, such as screen printing the solder mask layer 28 to the underlying surface. The solder mask layer 28 may be formed from any appropriate solder mask material (such as plastics, resins, acrylics, urethanes, and polyimides), and if formed from an electrically insulative material, the solder mask layer 28 can remain on the finally packaged device. To reduce the amount of warpage and delamination in the package assembly 29, the solder mask layer 28, conductive layers 23, 24 and carrier substrate layer(s) 20 may be formed from materials having similar coefficients of thermal expansion. While any desired fabrication technique may be used to form the solder mask layer 28 having a plurality of differently-sized solder ball apertures 25, 26, selected embodiments of the present invention use a photolithography process whereby a layer of photoimageable dielectric material (such as a photoresist) is formed over the upper and lower surfaces of the carrier substrate 20 (e.g., using spin-on techniques) and then selectively exposed or patterned, developed, and etched to form openings 25, 26 in the solder mask layer 28 over the upper surface of the carrier substrate 20. Alternatively, other techniques, such as screen printing techniques or stereolithography techniques, may be used to form a layer of dielectric material onto selected regions of the exposed carrier substrate 28, conductive traces and contact areas, thereby forming the solder mask layer 28. Thus, the solder mask layer 28 may be formed from a single layer or from a plurality of contiguous, at least partially superimposed, mutually adhered layers of dielectric material. Whichever fabrication process is used to form the openings in the solder mask layer 28 over the upper surface of the carrier substrate, openings may also be formed over the lower surface of the carrier substrate to expose the first contact pads or layers 23 for subsequent wirebond connection to the integrated circuit die, as depicted by way of example in FIG. 2.

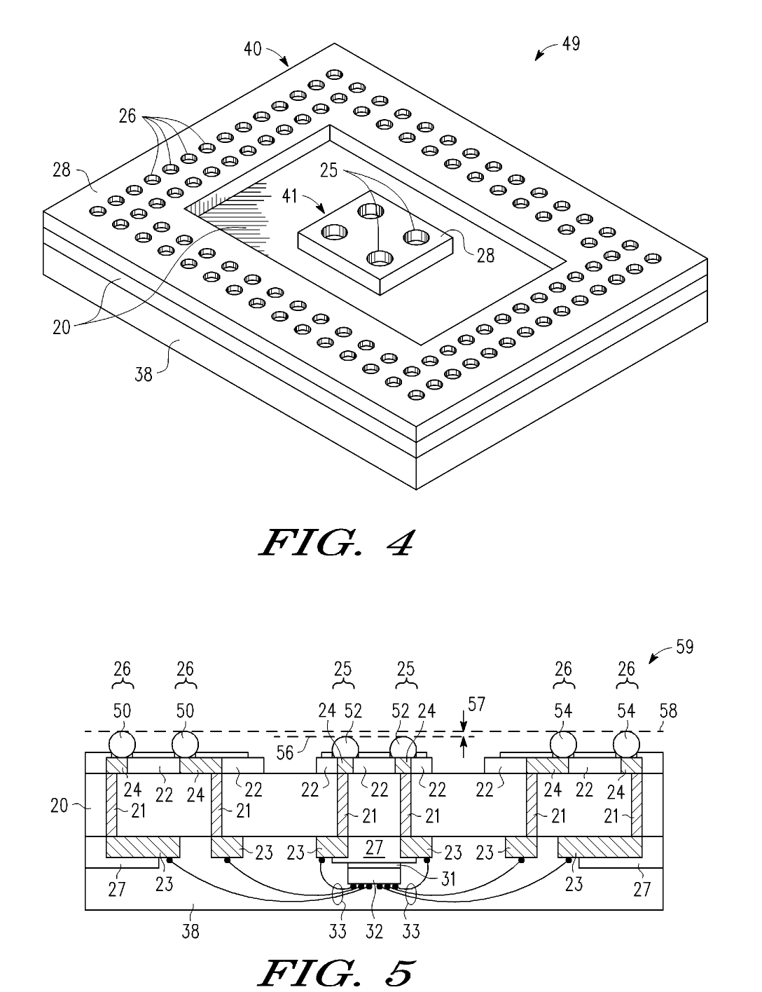

Referring now to FIG. 3, there is illustrated in cross-sectional form a packaging assembly 39 after attachment to an integrated circuit die 32, attachment of wirebonding 33 and formation of an encapsulation layer 38. The integrated circuit die 32 may be attached directly to the carrier substrate 20 or using an adhesive layer 31 (such as die attach epoxy) to attach the integrated circuit die 32 to a solder mask layer 28 on the lower surface of the carrier substrate 20 using techniques known in the art. As will be appreciated, an active surface of the integrated circuit die 32 includes one or more bond pads (not shown) that provide electrical connection to the circuitry (not shown) in the integrated circuit die 32. In turn, each bond pad of the integrated circuit die 32 may be electrically connected to its corresponding first contact pads or layer 23 on the carrier substrate 20 using an intermediate conductive element 33 (such as a bond wire, a thermosonic ball bond, a conductive TAB element carried upon a flexible dielectric film, a bonded lead, or the like). Once the intermediate conductive elements 33 are formed to electrically connect the integrated circuit die 32 to the carrier substrate 20, an encapsulation layer or material 38 may be formed to seal and protect the conductive elements inside the packaging assembly 49 from moisture, contamination, corrosion, and mechanical shock, such as by applying, injecting or otherwise forming a protective layer to seal the open region. For example, a transfer molding compound 38 may be formed over the integrated circuit die 32 using any desired technique to electrically isolate, physically secure and otherwise protect and package the die 32. Though wirebonding electrical connection techniques are illustrated in FIG. 3, it will be appreciated that flip-chip electrical connection techniques may be used to connect the integrated circuit die 32 to the packaging assembly 39 without requiring wirebonding.

To illustrate an example of a wire-bonded plastic ball grid array package implementation, FIG. 4 depicts a perspective view of a packaging assembly 49 in which an integrated circuit die (not shown) is physically attached to the carrier substrate 20 and encapsulated with a mold compound structure 38. As depicted, the packaging assembly 49 includes a solder mask layer 28 that is formed over an upper surface of the carrier substrate 20, where the solder mask layer 28 includes a plurality of openings 25, 26 formed to expose underlying conductive contact pads or layers (not shown) which are electrically connected to the encapsulated integrated circuit die. In the example shown in FIG. 4, an open region separates the solder mask layer 28 into two sections—a first inner section 41 that overlies a central or interior region of the carrier substrate 20 and a second outer section 40 that overlies a peripheral or exterior region of the carrier substrate 20. However, as mentioned above, the open region is not required, and the solder mask layer may instead be formed as a continuous layer in which only the solder mask layer openings 25, 26 are formed. Though a single open region is shown in FIG. 4 for separating the peripheral solder ball aperture openings 26 from the interior solder ball aperture openings 25, it will be appreciated that other designs and configurations may be used in defining the location and placement of the solder ball aperture openings 25, 26.

After attachment, connection and encapsulation of the integrated circuit die to the packaging assembly 49, solder balls or other discrete conductive elements 50, 52, 54 may then be formed as shown in FIG. 5, which illustrates in cross-sectional form a packaging assembly 59 after solder balls 50, 52, 54 are formed in differently-sized solder ball aperture openings 25, 26 to control the relative protrusions of solder balls from the packaged array. As will be appreciated, the solder balls 50, 52, 54 may be formed with any desired process, such as by affixing uniformly-sized eutectic solder balls or other discrete conductive elements 50, 52, 54 in the apertures 25, 26 of the solder mask layer 28 and on the second contact areas 24 of the carrier substrate 20.

In the example depicted in FIG. 5, the first group of solder ball aperture openings 25 (located in a central area of the carrier substrate) have a larger diameter than the second group of solder ball aperture openings 26 (located in a peripheral area of the carrier substrate), though the size of individual solder ball aperture openings over the carrier substrate may be varied as desired to control the relative height of the solder balls. For purposes of illustration only, the relative height effect of varying the size of the solder ball aperture openings may be shown with reference to a plurality of uniformly-sized solder balls having a diameter of 0.6 mm. When a 0.6 mm diameter solder ball is placed in a solder ball aperture opening having a first (relatively small) diameter of 0.5 mm, the solder ball is positioned at a first (relatively high) height in relation to the carrier substrate (e.g., 0.162 mil). As the diameter of the solder ball aperture opening is increased, the height of the solder ball decreases. For example, by increasing the diameter of the solder ball aperture opening by 20 μm (which is a 4% increase in the diameter of the opening), the relative height of the solder ball drops to 0.001 mil, and by increasing the diameter of the solder ball aperture opening by 40 μm (which is a 8% increase in the diameter of the opening), the relative height of the solder ball drops to −0.222 mil. Likewise, if the diameter of the solder ball aperture opening is increased by 60 μm (which is a 12% increase in the diameter of the opening), the relative height of the solder ball drops to −0.339 mil, and if the diameter of the solder ball aperture opening is increased by 80 μm (which is a 16% increase in the diameter of the opening), the relative height of the solder ball drops to −0.495 mil. As a result, an increase of the diameter of the solder ball aperture opening by 40 μm reduces the relative height by 0.38 mil, and an increase of the diameter of the solder ball aperture opening by 80 μm reduces the relative height by 0.66 mil.

As described hereinabove, the effect of warpage on a ball grid array substrate may be counteracted by varying the diameters of the solder mask openings across the packaging assembly 29. For example, by using larger diameter openings 25 where the warpage is lower (e.g., in the central or inner section 41), the increased effective pad diameter area provides more area for the solder ball to collapse on, thereby reducing the ball height in relation to the underlying carrier substrate 20. Conversely, by using smaller diameter openings 26 where the warpage is higher (e.g., in the outer or peripheral section 40), the smaller effective pad diameter area effectively reduces the area for the solder ball to collapse on, thereby increasing the ball height in relation to the underlying carrier substrate 20. The ball height variation resulting from the varied solder mask opening diameter can compensate for package warpage. The relatively higher position of the solder balls 50, 54 formed in the smaller diameter solder mask openings 26 is indicated with the dashed alignment line 58, while the relatively lower position of the solder balls 52 formed in the larger diameter solder mask openings 25 is indicated with the dashed alignment line 56. In particular and as indicated by the arrows at 57, the solder balls 50, 54 (which are formed in the relatively narrow solder ball openings 26) have an increased relative ball height 58 as compared to the solder balls 52 which collapse more deeply into the wider solder ball openings 25 and have a lower relative height 56. Of course, the location and placement of the varied size solder openings can be adjusted as needed to account for warpage effects in the ball grid array substrate. In addition, it will be appreciated that three or more different ball heights can be produced by varying the diameters of the solder mask openings. For example, if it is determined that the effects of package warpage would produce two or more different ball heights (e.g., a first height in a first corner exterior region, and a second, shorter height in a second corner exterior region, and a third, shortest height in the interior region), then the diameters of the solder mask openings in the different regions would be adjusted to reduce the effects of the warpage. For example, the diameters of the solder mask openings in the first corner can be reduced relative to the diameters of the solder mask openings in the second corner and interior regions, while the diameters of the solder mask openings in the interior region can be increased relative to the diameters of the solder mask openings in the first and second corner regions.

By now it should be appreciated that there has been provided a method for making a package assembly, such as a ball grid array package, by forming solder mask openings having varied diameters. Under the method, a carrier substrate is provided which has a conductive pattern (including a plurality of bonding pads) disposed on its surface, and a solder mask layer is formed over the carrier substrate surface to cover all or part of the conductive pattern. As formed, the solder mask layer includes solder ball aperture openings corresponding in location to the bonding pads, where the solder ball aperture openings include a first solder ball aperture opening having a first diameter and a second solder ball aperture opening having a second diameter that is larger than the first diameter. The solder mask layer can be formed by affixing a preformed solder mask layer to the carrier substrate, where the plurality of solder ball aperture openings are preformed in the preformed solder mask layer. Alternatively, the solder mask layer can be formed by depositing a solder mask layer and then selectively etching the solder ball aperture openings to thereby expose the plurality of bonding pads. In the solder ball aperture openings, solder balls are affixed to each bonding pad so that a solder ball affixed in the first solder ball aperture opening has a higher relative height in comparison to the carrier substrate than a solder ball affixed in the second solder ball aperture opening. At an appropriate point during package assembly, an integrated circuit die is secured to a second surface of the carrier substrate to electrically connect circuitry in the integrated circuit die to the conductive pattern in the carrier substrate. In various embodiments, the effects of warpage are reduced by locating the first solder ball aperture openings in a first area of the carrier substrate where warpage is higher (e.g., in a peripheral area of the carrier substrate) and by locating the second solder ball aperture openings in a second area of the carrier substrate where warpage is lower (e.g., in a central area of the carrier substrate).

In another form, a method is provided for fabricating a semiconductor device package, such as a wire-bonded plastic ball grid array package for an integrated circuit die, by forming solder ball mounting layer over a carrier substrate with a plurality of solder ball openings having different sizes so that solder balls may be affixed to the carrier substrate at different heights based on the size of the solder ball opening. In a selected embodiment, a carrier substrate having a first surface and a second surface is provided. At least one of the first and second surfaces includes a plurality of conductors and/or at least one semiconductor device attach site for attachment of a semiconductor device. Over at least part of either surface of the carrier substrate, a solder ball mounting layer is formed having a plurality of solder ball openings of different sizes such that each of the plurality of solder ball openings exposes an underlying conductor. The mounting layer may be formed from one or more solder ball mask layers, though other materials may be used, such as non-solder mask layers. The differently sized solder ball openings may be located and positioned in any desired arrangement. For example, the solder ball mounting layer may include a first solder ball mounting layer over a peripheral region of the carrier and a second solder ball mounting layer over an interior region of the carrier substrate, where the first solder ball mounting layer has formed therein a first plurality of solder ball openings having a first diameter and where the second solder ball mounting layer has formed therein a second plurality of solder ball openings having a second solder ball aperture openings having a second diameter that is larger than the first diameter. A variety of techniques may be used to form the solder ball mounting layer. In one example embodiment, the solder ball mounting layer is provided by affixing a preformed or screen-printed solder mask layer to the carrier substrate, where a plurality of solder ball aperture openings are preformed in the preformed solder mask layer. In another example embodiment, the solder ball mounting layer is provided by depositing a solder ball mounting layer over the first surface of the substrate to cover at least part of the plurality of conductors formed on the first surface, and then selectively etching a plurality of solder ball openings in the solder ball mounting layer to thereby expose the plurality of conductors formed on the first surface, where the plurality of solder ball openings comprises a first solder ball opening having a first diameter and a second solder ball opening having a second diameter that is larger than the first diameter. After forming the solder ball mounting layer, a solder ball is affixed through each of the plurality of solder ball openings to an exposed underlying conductor so that a plurality of solder balls are affixed to the carrier substrate at different heights based on the different sizes of the solder ball openings.

In still yet another form, a method is provided for fabricating a ball grid array package by providing a ball grid array substrate having a plurality of conductive contact pads formed on an underlying substrate, where the ball grid array substrate includes a plurality of solder ball openings having varied diameters to expose therethrough the plurality of conductive contact pads. By forming solder ball openings with different sizes and placing the bolder ball openings appropriately, warpage can be reduced. For example, the ball grid array substrate may include at least a first solder ball opening having a first relatively larger diameter opening in areas where the warpage of the ball grid array substrate is lower, and may include at least a second solder ball opening having a second relatively smaller diameter opening in areas where the warpage of the ball grid array substrate is higher. In an example implementation, the first relatively larger diameter opening is substantially between 4-16 percent larger in diameter than the second relatively smaller diameter opening. In another example implementation, the first relatively larger diameter opening is substantially 40 μm larger in diameter than the second relatively smaller diameter opening, thereby reducing a first relative height of a solder ball placed in the first relatively larger diameter opening by substantially 0.38 mils as compared to a second relative height of a solder ball placed in the second relatively smaller diameter opening. In yet another example implementation, the first relatively larger diameter opening is substantially 80 μm larger in diameter than the second relatively smaller diameter opening, thereby reducing a first relative height of a solder ball placed in the first relatively larger diameter opening by substantially 0.66 mils as compared to a second relative height of a solder ball placed in the second relatively smaller diameter opening. A variety of techniques may be used to fabricate the ball grid array substrate. In one example embodiment, the ball grid array substrate is fabricated by forming a solder mask layer over a first surface of the underlying substrate, where the solder mask layer includes a plurality of solder ball openings corresponding in location to the conductive contact pads, including a first solder ball opening having a first diameter and a second solder ball opening having a second diameter that is larger than the first diameter. Once the ball grid array package is provided, a solder ball may be affixed through each of the plurality of solder ball openings to an exposed underlying conductive contact pad so that a plurality of solder balls are affixed to the ball grid array substrate at different heights based on the different sizes of the solder ball openings. In addition, an integrated circuit die may be secured to the ball grid array substrate to electrically connect circuitry in the integrated circuit die to a conductive pattern formed in the ball grid array substrate.

In another form, there is disclosed a ball grid array package for packing a semiconductor device. The ball grid array package includes a carrier substrate having a first surface in which is formed a plurality of conductive contact pads, which may in turn be electrically connected to a conductive pattern of traces, vias and other contact pad areas in the carrier substrate. In addition, a solder mask layer is formed on the first surface of the carrier substrate, where the solder mask layer has formed therein a plurality of solder ball aperture openings corresponding in location to the plurality of conductive contact pads. These solder ball aperture openings include a first solder ball aperture opening having a first diameter and a second solder ball aperture opening having a second diameter that is larger than the first diameter. The ball grid array package may also include an integrated circuit die that is affixed and electrically connected to the carrier substrate using any desired technique, such as wirebonding or flip-chip techniques. In addition, solder balls may be affixed in the plurality of solder ball aperture openings to make electrical contact to the underlying conductive contact pads, which in turn are electrically connected to the integrated circuit die.

Although the described exemplary embodiments disclosed herein are directed to various packaging assemblies and methods for making same, the present invention is not necessarily limited to the example embodiments which illustrate inventive aspects of the present invention that are applicable to a wide variety of packaging processes and/or devices. For example, other integrated circuit die attachment and connection configurations may be used, such as, for example, affixing the integrated circuit die to the bottom side of the carrier substrate and using wire conductors to electrically connect the die to conductive layers or contact pads on the upper side of the carrier substrate through one or more openings formed in the carrier substrate. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a package assembly, comprising:
providing carrier substrate having a conductive pattern disposed on a first surface of the carrier substrate, where the conductive pattern comprises a plurality of bonding pads;
forming a solder mask layer over the first surface of the carrier substrate to cover at least part of the conductive pattern, where the solder mask layer comprises a plurality of solder ball aperture openings corresponding in location to the plurality of bonding pads, where the plurality of solder ball aperture openings comprises a first solder ball aperture opening having a first diameter and a second solder ball aperture opening having a second diameter that is larger than the first diameter; and
affixing a solder ball to each bonding pad through a corresponding solder ball aperture opening so that a solder ball affixed in the first solder ball aperture opening has a higher relative height in comparison to the carrier substrate than a solder ball affixed in the second solder ball aperture opening.

2. The method of claim 1, further comprising securing an integrated circuit die to a second surface of the carrier substrate and electrically connecting circuitry in the integrated circuit die to the conductive pattern in the carrier substrate.

3. The method of claim 1, where forming a solder mask layer comprises:
depositing a solder mask layer over the first surface of the carrier substrate to cover at least part of the conductive pattern; and
selectively etching a plurality of solder ball aperture openings in the solder mask layer corresponding in location to the plurality of bonding pads to thereby expose the plurality of bonding pads, where the plurality of solder ball aperture openings comprises a first solder ball aperture opening having a first diameter and a second solder ball aperture opening having a second diameter that is larger than the first diameter.

4. The method of claim 1, where forming a solder mask layer comprises affixing a preformed solder mask layer to the carrier substrate, where the plurality of solder ball aperture openings are preformed in the preformed solder mask layer.

5. The method of claim 1, where the first solder ball aperture opening is located in a peripheral area of the carrier substrate and the second solder ball aperture opening is located in a central area of the carrier substrate.

6. The method of claim 1, where the first solder ball aperture opening is located in a first area of the carrier substrate where warpage is higher and the second solder ball aperture opening is located in a second area of the carrier substrate where warpage is lower.

7. The method of claim 1, where forming a solder mask layer comprises applying a quantity of photoimageable material over the first surface of the carrier substrate and selectively curing the photoimageable material through a mask layer by exposing selected regions of the photoimageable material.

8. The method of claim 1, where the carrier substrate comprises a ball grid array substrate.

9. A method for fabricating a semiconductor device package, comprising:
providing a substrate having a first surface and a second surface, at least one of the first and second surfaces including a plurality of conductors, at least one of the first and second surfaces comprising at least one semiconductor device attach site for attachment of a semiconductor device; and
forming a solder ball mounting layer over at least part of at least one of the first and second surfaces, where the solder ball mounting layer has formed therein a plurality of solder ball openings having different sizes such that each of the plurality of solder ball openings exposes an underlying conductor.

10. The method of claim 9, comprising affixing a solder ball through each of the plurality of solder ball openings to an exposed underlying conductor so that a plurality of solder balls are affixed to the substrate at different heights based on the different sizes of the solder ball openings.

11. The method of claim 9, where the semiconductor device package comprises a wire-bonded plastic ball grid array package.

12. The method of claim 9, where the solder ball mounting layer comprises a solder ball mask layer.

13. The method of claim 9, where forming a solder ball mounting layer over at least part of at least one of the first and second surfaces comprises:
forming a first solder ball mounting layer over a peripheral region of the substrate, where the first solder ball mounting layer has formed therein a first plurality of solder ball openings having a first diameter; and
forming a second solder ball mounting layer over an interior region of the substrate, where the second solder ball mounting layer has formed therein a second plurality of solder ball openings having a second solder ball aperture openings having a second diameter that is larger than the first diameter.

14. The method of claim 9, where forming a solder ball mounting layer comprises affixing a screen-printed solder mask layer to the substrate, where a plurality of solder ball aperture openings are preformed in the preformed solder mask layer.

15. The method of claim 9, where forming a solder ball mounting layer comprises affixing a preformed solder mask layer to the substrate, where the plurality of solder ball openings are preformed in the preformed solder mask layer.

16. The method of claim 9, where forming a solder ball mounting layer comprises:
depositing a solder ball mounting layer over the first surface of the substrate to cover at least part of the plurality of conductors formed on the first surface; and
selectively etching a plurality of solder ball openings in the solder ball mounting layer to thereby expose the plurality of conductors formed on the first surface, where the plurality of solder ball openings comprises a first solder ball opening having a first diameter and a second solder ball opening having a second diameter that is larger than the first diameter.

17. A method of fabricating a ball grid array package, comprising:
providing a ball grid array substrate comprising a plurality of conductive contact pads formed on an underlying substrate, where the ball grid array substrate comprises a plurality of solder ball openings having varied diameters to expose therethrough the plurality of conductive contact pads;
where at least a first solder ball opening formed in the ball grid array substrate has a first relatively larger diameter opening in areas where warpage of the ball grid array substrate is lower and where at least a second solder ball opening formed in the ball grid array substrate has a second relatively smaller diameter opening in areas where warpage of the ball grid array substrate is higher.

18. The method of claim 17, comprising affixing a solder ball through each of the plurality of solder ball openings to an exposed underlying conductive contact pad so that a plurality of solder balls are affixed to the ball grid array substrate at different heights based on the different sizes of the solder ball openings.

19. The method of claim 17, further comprising securing an integrated circuit die to the ball grid array substrate and electrically connecting circuitry in the integrated circuit die to a conductive pattern formed in the ball grid array substrate.

20. The method of claim 17, where providing a ball grid array substrate comprises forming a solder mask layer over a first surface of the underlying substrate, where the solder mask layer comprises a plurality of solder ball openings corresponding in location to the plurality of conductive contact pads, where the plurality of solder ball openings comprises a first solder ball opening having a first diameter and a second solder ball opening having a second diameter that is larger than the first diameter.

21. The method of claim 17, where the first relatively larger diameter opening is substantially between 4-16 percent larger in diameter than the second relatively smaller diameter opening.

22. The method of claim 17, where the first relatively larger diameter opening is substantially 40 μm larger in diameter than the second relatively smaller diameter opening, thereby reducing a first relative height of a solder ball placed in the first relatively larger diameter opening by substantially 0.38 mils as compared to a second relative height of a solder ball placed in the second relatively smaller diameter opening.

23. The method of claim 17, where the first relatively larger diameter opening is substantially 80 μm larger in diameter than the second relatively smaller diameter opening, thereby reducing a first relative height of a solder ball placed in the first relatively larger diameter opening by substantially 0.66 mils as compared to a second relative height of a solder ball placed in the second relatively smaller diameter opening.

24. A ball grid array package for packing a semiconductor device, comprising:
a carrier substrate comprising a first surface in which is formed a plurality of conductive contact pads; and
a solder mask layer formed on the first surface of the carrier substrate, where the solder mask layer comprises a plurality of solder ball aperture openings corresponding in location to the plurality of conductive contact pads, where the plurality of solder ball aperture openings comprises a first solder ball aperture opening having a first diameter and a second solder ball aperture opening having a second diameter that is larger than the first diameter.
